(19) United States
(12) Patent Application Publication
(10) Pub. No.: US 2026/0318958 A1
(43) Pub. Date: Oct. 15, 2026

(54) CURRENT MEASURING DEVICE

(71) Applicant: Asahi Kasei Microdevices Corporation, Tokyo (JP)

(72) Inventors: Keita YAMAGUCHI, Tokyo (JP); Miho ONUMA, Tokyo (JP); Masaki TSUJIMOTO, Tokyo (JP)

(21) Appl. No.: 19/696,269

(22) Filed: Jun. 2, 2026

Related U.S. Application Data
(63) Continuation of application No. PCT/JP2024/043672, filed on Dec. 10, 2024.

(30) Foreign Application Priority Data
Dec. 13, 2023 (JP) 2023-209742

(51) Int. Cl. G01R 19/00; G01D 11/24; G01R 15/20

(52) U.S. Cl. CPC G01R 19/0092; G01D 11/245; G01R 15/207

(57) ABSTRACT

A current measuring device includes a first bus bar and a first current sensor arranged on a first surface of a substrate, and a second bus bar and a second current sensor arranged on a second surface of the substrate. A first sealing portion of the first current sensor and a second sealing portion of the second current sensor overlap in a thickness direction of the substrate. A first magnetoelectric conversion element of the first current sensor and a second primary conductor portion of the second current sensor do not overlap in the thickness direction of the substrate in plan view. A second magnetoelectric conversion element of the second current sensor and a first primary conductor portion of the first current sensor do not overlap in the thickness direction of the substrate in plan view.

The contents of the following patent application(s) are incorporated herein by reference:
NO. 2023-209742 filed in JP on Dec. 13, 2023
NO. PCT/JP2024/043672 filed in WO on Dec. 10, 2024.

### BACKGROUND

### 1. Technical Field

The present invention relates to a current measuring device.

### 2. Related Art

Patent Document 1 discloses a current sensor in which a pair of magnetic sensors arranged opposite to each other via a bus bar are arranged at equal distances from the bus bar arranged between another pair of magnetic sensors, and the other pair of magnetic sensors are arranged at equal distances from the bus bar. Patent Document 2 discloses a current sensor in which a plurality of bus bars having convex portions are arranged shifted from each other, and two magnetoelectric conversion units are arranged opposite to each other with a part of each convex portion sandwiched therebetween in plan view.

### RELATED ART DOCUMENTS

### Patent Documents

Patent Document 1: International Publication No. 2015/033541

Patent Document 2: Japanese Patent Publication Application No. 2022-100597

### BRIEF DESCRIPTION OF THE DRAWINGS

FIG. 1A is a schematic plan view of the current sensor used in the current measuring device according to the first embodiment, as viewed from the ceiling surface side (Z-axis direction).

FIG. 1B is a cross-sectional view taken along line A-A of the current sensor shown in FIG. 1A.

FIG. 2A is a plan view of the substrate as viewed from the first surface side on which one current sensor is mounted, in the current measuring device according to the first embodiment.

FIG. 2B is a plan view of the substrate as viewed from the second surface side opposite to the first surface on which another current sensor is mounted, in the current measuring device according to the first embodiment.

FIG. 2C is a schematic cross-sectional view of the substrate in a state in which two current sensors are mounted, as viewed from the negative side to the positive side in the X-axis direction, in the current measuring device according to the first embodiment.

FIG. 2D is the schematic cross-sectional view of the substrate in a state in which two current sensors are mounted, as viewed from the positive side to the negative side in the Y-axis direction, in the current measuring device according to the first embodiment.

FIG. 3 is a schematic plan view in which, in the current measuring device according to the first embodiment, the substrate is viewed from the first surface side, and another current sensor arranged on the second surface side and the bus bar through which current of the second phase flows are indicated by broken lines.

FIG. 4 is a diagram showing an example of simulation results showing the magnitude of a current error detected by one current sensor or another current sensor according to the distance (mm) in the X-axis direction between the centroid of one current sensor and the centroid of another current sensor, when viewed in plan view, in the current measuring device according to the first embodiment.

FIG. 5 is a schematic plan view of a modified example in which, with the substrate viewed from the first surface side, another current sensor arranged on the second surface side and the bus bar through which current of the second phase flows are indicated by broken lines.

FIG. 6 is a schematic cross-sectional view of the substrate in a state in which two current sensors are mounted, as viewed from the negative side to the positive side in the X-axis direction, according to the modified example in which the bus bar through which current of the third phase flows is arranged in the inner layer.

FIG. 7A is a plan view of the substrate as viewed from the first surface side on which one current sensor is mounted, in the current measuring device according to the second embodiment.

FIG. 7B is a plan view of the substrate as viewed from the second surface side opposite to the first surface on which another current sensor is mounted, in the current measuring device according to the second embodiment.

FIG. 7C is the schematic cross-sectional view of the substrate in a state in which two current sensors are mounted, as viewed from the negative side to the positive side in the X-axis direction, in the current measuring device according to the second embodiment.

FIG. 7D is the schematic cross-sectional view of the substrate in a state in which two current sensors are mounted, as viewed from the positive side to the negative side in the Y-axis direction, in the current measuring device according to the second embodiment.

FIG. 8 is a schematic plan view in which, in the current measuring device according to the second embodiment, the substrate is viewed from the first surface side, and another current sensor arranged on the second surface side and the bus bar through which current of the second phase flows are indicated by broken lines.

FIG. 9 is a diagram showing an example of simulation results showing the magnitude of a current error detected by one current sensor or another current sensor according to the distance (mm) in the X-axis direction between the centroid of one current sensor and the centroid of another current sensor, when viewed in plan view, in the current measuring device according to the second embodiment.

FIG. 10 is a schematic plan view of a modified example in which, in the current measuring device according to the second embodiment, the substrate is viewed from the first surface side, and another current sensor arranged on the second surface side and the bus bar through which current of the second phase flows are indicated by broken lines.

FIG. 11 is a schematic cross-sectional view of the substrate in a state in which in the current measuring device according to the second embodiment, two current sensors are mounted, as viewed from the negative side to the positive side in the X-axis direction, according to a modified example in which the bus bar through which current of the third phase flows is arranged in the inner layer.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

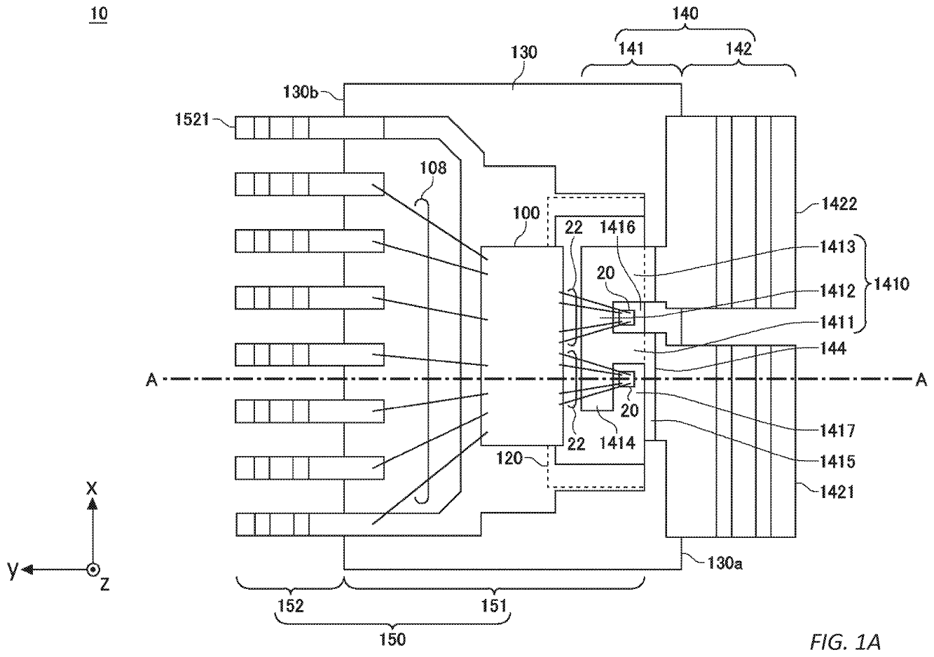

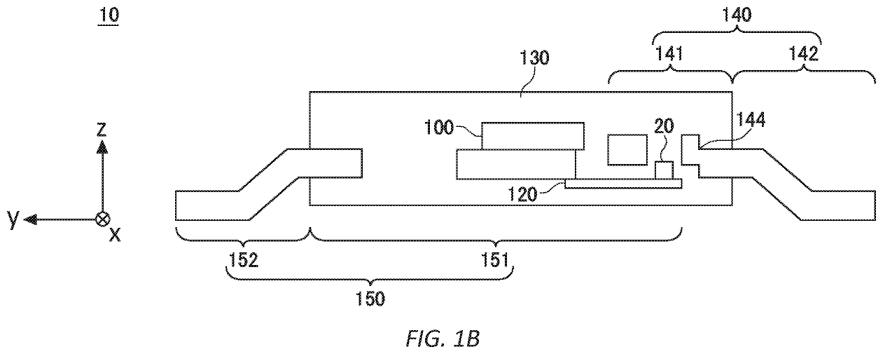

FIGS. 1A and 1B illustrate the internal configuration of the semiconductor package functioning as the current sensor 10 used in the current measuring device according to the first embodiment. FIG. 1A is a schematic plan view of the current sensor 10 as viewed from the ceiling surface side (Z-axis direction). FIG. 1B is the cross-sectional view taken along line A-A of the current sensor 10 shown in FIG. 1A. The current sensor 10 shown in FIGS. 1A and 1B is merely an example, and the current sensor used in the current measuring device according to the present embodiment is not limited to the current sensor 10 shown in FIGS. 1A and 1B.

The coordinates are defined in FIG. 1A such that the direction from bottom to top and parallel to the plane of the paper is the X-axis direction, the direction from right to left and parallel to the plane of the paper is the Y-axis direction, and the direction from back to front and perpendicular to the plane of the paper is the Z-axis direction. Any one of the X-axis, the Y-axis, and the Z-axis is orthogonal to the other axes.

The current sensor 10 includes a signal processing IC 100, two magnetoelectric conversion elements 20, a primary lead frame 140 on the current conductor side, a secondary lead frame 150 on the signal terminal side, a support portion 120, and the sealing portion 130. In the present embodiment, an example in which the current sensor 10 includes two magnetoelectric conversion elements 20 will be described. However, the number of magnetoelectric conversion elements 20 included in the current sensor 10 is not limited to two. The current sensor 10 need only include at least one magnetoelectric conversion element 20.

The primary lead frame 140 includes a primary conductor portion 141 and a primary terminal portion 142. The primary terminal portion 142 includes a pair of primary terminals 1421 and 1422. The primary conductor portion 141 is sealed in the sealing portion 130 and partially surrounds the two magnetoelectric conversion elements 20. The measurement current flows through the primary terminal portion 142 and the primary conductor portion 141. The pair of primary terminals 1421 and 1422 are physically integrated with the primary conductor portion 141 and are exposed outside the sealing portion 130.

The primary lead frame 140 does not need to be manufactured in a form in which a plurality of metal plates are connected to constitute the primary conductor portion 141 and the primary terminal portion 142, and may be manufactured using separated metal parts.

The secondary lead frame 150 includes the IC support portion 151 and the secondary terminal portion 152. The secondary terminal portion 152 includes a plurality of secondary terminals 1521 that are signal terminals. The IC support portion 151 is sealed in the sealing portion 130 and supports the signal processing IC 100. Some of the plurality of secondary terminals 1521 are physically integrated with the IC support portion 151. At least part of each of the plurality of secondary terminals 1521 is exposed outside the sealing portion 130. The primary lead frame 140 and the secondary lead frame 150 may be constituted by a conductive material, the main component of which is copper. The IC support portion 151 may be constituted by the metal plate separate from the secondary lead frame 150, a plate made of semiconductor, or an insulating member such as a die attach film.

The element support portion 120 is supported by the IC support portion 151 and supports the two magnetoelectric conversion elements 20. The element support portion 120 is constituted by the separate metal plate, a plate made of semiconductor, or an insulating member such as a die attach film. The element support portion 120 may be integrally constituted with the IC support portion 151.

The pair of primary terminals 1421 and 1422 and the plurality of secondary terminals 1521 are arranged to face each other with the signal processing IC 100 interposed therebetween in a direction (Y-axis direction) intersecting the thickness direction (Z-axis direction) of the signal processing IC 100. The direction intersecting the thickness direction may be a direction along the plane (XY plane) orthogonal to the thickness direction. The pair of primary terminals 1421 and 1422 are exposed from the side surface 130a of the sealing portion 130. The plurality of secondary terminals 1521 are exposed from the side surface 130b opposite to the side surface 130a of the sealing portion 130.

The pair of primary terminals 1421 and 1422 protrude from the side surface 130a toward the negative side in the Y-axis direction, and are further bent toward the negative side in the Z-axis direction. The plurality of secondary terminals 1521 protrude from the side surface 130b toward the positive side in the Y-axis direction, and are further bent toward the negative side in the Z-axis direction. The pair of primary terminals 1421 and 1422 may protrude from the side surface 130a toward the negative side in the Y-axis direction, and may further be bent toward the positive side in the Z-axis direction. The plurality of secondary terminals 1521 may protrude from the side surface 130b toward the positive side in the Y-axis direction, and may further be bent toward the positive side in the Z-axis direction. The pair of primary terminals 1421 and 1422 and the plurality of secondary terminals 1521 may not be bent. That is, the pair of primary terminals 1421 and 1422 may protrude from the side surface 130a toward the negative side in the Y-axis direction and may not be bent toward the positive side and the negative side in the Z-axis direction. The plurality of secondary terminals 1521 may protrude from the side surface 130b toward the positive side in the Y-axis direction and may not be bent toward the positive side and the negative side in the Z-axis direction.

The signal processing IC 100 may be fixed to the IC support portion 151 via the adhesive layer. The adhesive layer may be the die attach film. The primary lead frame 140 may have a step portion 144 in which a facing portion facing the signal processing IC 100 protrudes in a direction away from the signal processing IC 100 in the thickness direction.

The primary conductor portion 141 has the bent portion 1410 that connects the primary terminal 1421 and the primary terminal 1422. The bent portion 1410 includes a portion 1411 connected to the primary terminal 1421 and extending in the Y-axis direction, a portion 1413 connected to the primary terminal 1422 and extending in the Y-axis direction, and a connecting portion 1412 extending in the X-axis direction and connecting the portion 1411 and the portion 1413. The bent portion 1410 has the U-shaped portion constituted by the portion 1411, the connecting portion 1412, and the portion 1413. The portion 1411, the connecting portion 1412, and the portion 1413 constitute the slit 1416 having an opening on the negative side in the Y-axis direction. The bent portion 1410 further has the extension 1414 extending further from the connecting portion 1412 toward the negative side in the X-axis direction. The extension 1414, the portion 1411, and the connection 1415 with the primary terminal 1421 constitute a slit 1417 having an opening on the negative side in the X-axis direction. The portion 1411 is an example of the first portion and the third portion. The portion 1413 is an example of the second portion and the fourth portion.

One magnetoelectric conversion element 20 is partially surrounded by the primary conductor portion 141 by being arranged in the slit 1416 in plan view. Another magnetoelectric conversion element 20 is partially surrounded by the primary conductor portion 141 by being arranged in the slit 1417 in plan view. One magnetoelectric conversion element 20 and another magnetoelectric conversion element 20 are arranged to face each other with the portion 1411 interposed therebetween in plan view along the X-axis direction. The shape of the primary conductor portion 141 is not limited to the shape illustrated in FIG. 1A, and may be any shape.

The two magnetoelectric conversion elements 20 may be electrically connected to the signal processing IC 100 by wire bonding. That is, the two magnetoelectric conversion elements 20 may be electrically connected to the signal processing IC 100 via a plurality of wires 22. The two magnetoelectric conversion elements 20 output, to the signal processing IC 100, the signal to be processed by the signal processing IC 100. The two magnetoelectric conversion elements 20 may be configured separately from the signal processing IC 100. That is, the two magnetoelectric conversion elements 20 may be configured as chips separate from the chip constituting the signal processing IC 100.

The magnetic sensing surfaces of the two magnetoelectric conversion elements 20 may be arranged at positions overlapping side surfaces on which the slit portions 1416 and 1417 are provided, as viewed from a direction intersecting the thickness direction (Z-axis direction) of the two magnetoelectric conversion elements 20 (the X-axis direction or the Y-axis direction).

The signal processing IC 100 is electrically connected to the plurality of secondary terminals 1521 via the wire 108. The wire 22 and the wire 108 may be formed of a conductive material containing Au, Ag, Cu, or Al as a main component.

The magnetoelectric conversion element 20 detects a magnetic field in a specific direction that changes in accordance with a measurement current flowing through the primary conductor portion 141, and the signal processing IC 100 amplifies the signal corresponding to the magnitude of the magnetic field and outputs the amplified signal via the secondary terminal 1521. The magnetoelectric conversion element 20 may be the chip formed of the compound semiconductor formed on the GaAs substrate and cut into the square or rectangular shape in plan view from the Z-axis direction.

The magnetoelectric conversion element 20 may have a substrate made of silicon or a compound semiconductor, and a magnetoelectric conversion portion provided on the substrate. The thickness of the substrate is adjusted by polishing the surface on the negative side in the Z-axis direction. Since a magnetic field in the Z-axis direction is to be detected, for example, the Hall element that detects a vertical magnetic field in the thickness direction of the primary conductor portion 141 is suitable as the magnetoelectric conversion element 20.

The signal processing IC 100 is the large-scale integrated circuit (LSI). The signal processing IC 100 is a monolithic IC. More specifically, the signal processing IC 100 is the signal processing circuit made of the Si monolithic semiconductor formed on the Si substrate. The signal processing circuit processes output signals corresponding to the magnitudes of the magnetic fields output from the two magnetoelectric conversion elements 20. The signal processing circuit corrects, based on the output signal, the measurement current flowing through the primary conductor portion 141, and outputs, via the secondary terminal 1521, an output signal indicating the accurate current value. The signal processing circuit reduces noise components included in the output signal of one magnetoelectric conversion element 20 and the output signal of another magnetoelectric conversion element 20 based on a difference between the output signal of one magnetoelectric conversion element 20 and the output signal of another magnetoelectric conversion element 20, amplifies the output signal of one magnetoelectric conversion element 20 and the output signal of another magnetoelectric conversion element 20 from which the noise components have been reduced, calculates a current value of the measurement current based on the amplified output signals, and outputs an output signal indicating the current value.

The sealing portion 130 seals the magnetoelectric conversion element 20, the primary conductor portion 141, the IC support portion 151, the element support portion 120, the signal processing IC 100, the wire 22, and the wire 108 with the mold resin. The mold resin is composed, for example, of an epoxy thermosetting resin to which silica is added, and may be molded into the semiconductor package by transfer molding.

Using a plurality of current sensors 10 configured as described above, the current measuring device is configured to detect two-phase or three-phase currents among three-phase currents (U-phase, V-phase, and W-phase) output from a three-phase power source. In this embodiment, the current measuring device that detects the two-phase current will be described as an example.

The current measuring device according to the first embodiment includes the current sensor 10A and the current sensor 10B. The current sensor 10A and the current sensor 10B may have the same configuration as the above-described current sensor 10.

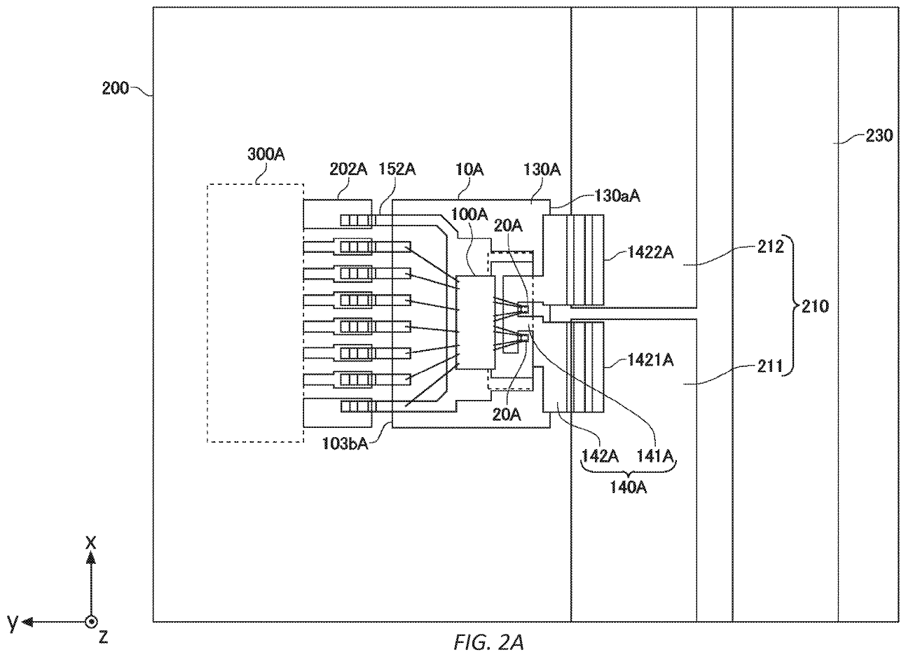

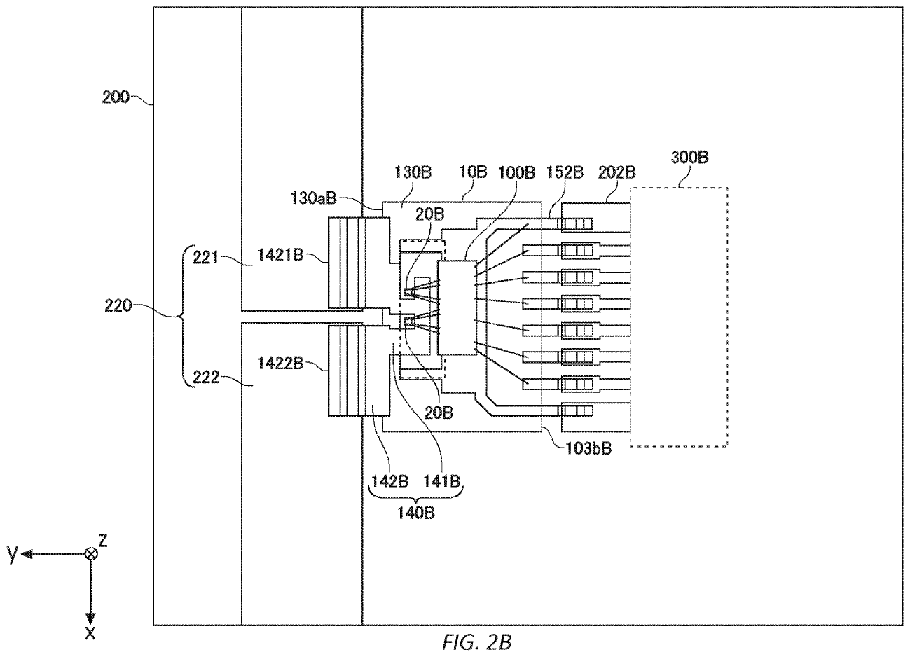

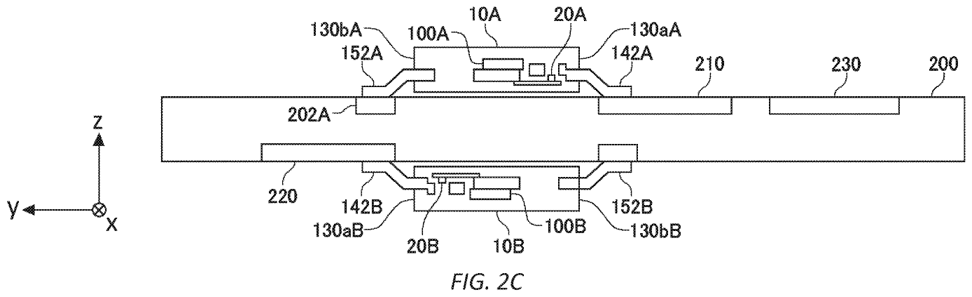

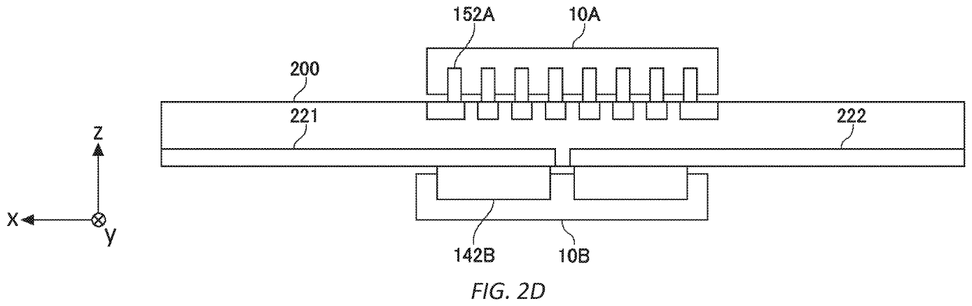

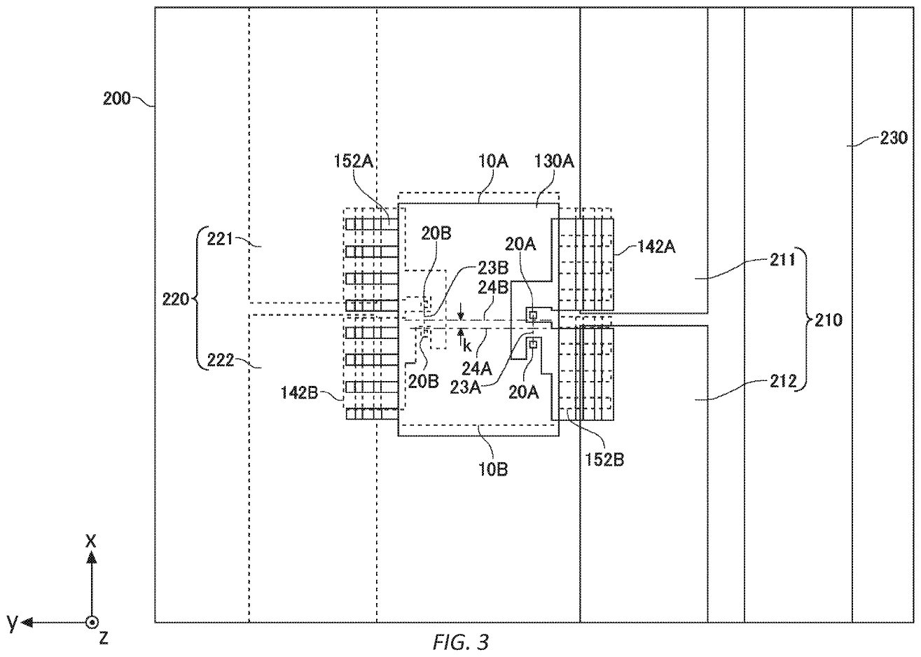

FIG. 2A is a plan view of the substrate 200 as viewed from the first surface side on which the current sensor 10A is mounted, in the first embodiment. FIG. 2B is a plan view of the substrate 200 as viewed from the second surface side opposite to the first surface on which the current sensor 10B is mounted, in the first embodiment. FIG. 2C is the schematic cross-sectional view of the substrate 200 in a state in which the current sensor 10A and the current sensor 10B are mounted, as viewed from the negative side toward the positive side in the X-axis direction, in the first embodiment. FIG. 2D is the schematic cross-sectional view of the substrate 200 in a state in which the current sensor 10A and the current sensor 10B are mounted, as viewed from the positive side toward the negative side in the Y-axis direction, in the first embodiment. FIG. 3 is a schematic plan view of the substrate 200 in a state in which the current sensor 10B and the bus bar 220 arranged on the second surface side are indicated by broken lines, as viewed from the first surface side, in the first embodiment.

The current measuring device includes, on the first surface of the substrate 200, the bus bar 210 that extends along the X-axis direction and through which current of a first phase flows. The current measuring device further includes, on the second surface of the substrate 200, the bus bar 220 that extends along the X-axis direction and through which current of a second phase flows. In addition, the current measuring device further includes, on the first surface of the substrate 200, the bus bar 230 that extends along the X-axis direction and through which current of a third phase flows. The bus bar 210, the bus bar 220, and the bus bar 230 may be arranged in parallel in plan view.

The current sensor 10A measures the current of the first phase flowing through the bus bar 210. The current sensor 10B measures the current of the second phase flowing through the bus bar 220. The circuit 300A including a power supply that supplies power to the current sensor 10A, a signal processing circuit that processes a signal output from the current sensor 10A, and the like is connected to the secondary terminal portion 152A of the current sensor 10A via the pad 202A on the first surface of the substrate 200. The circuit 300B including a power supply that supplies power to the current sensor 10B, a signal processing circuit that processes a signal output from the current sensor 10B, and the like is connected to the secondary terminal portion 152B of the current sensor 10B via the pad 202B on the second surface of the substrate 200. At least a part of the circuit 300A and the circuit 300B may be the common circuit.

The bus bar 210 has two divided conductor portions 211 and 212 extending along the Z-axis direction along the first surface of the substrate 200. The divided conductor portion 211 and the divided conductor portion 212 are spaced apart from each other. The primary terminal 1421A is connected to the divided conductor portion 211, and the primary terminal 1422A is connected to the divided conductor portion 212. The current of the first phase flows through the divided conductor portion 211, the primary lead frame 140, and the divided conductor portion 212.

The bus bar 220 has, like the bus bar 210, two divided conductor portions 221 and 222 extending along the X-axis direction along the second surface of the substrate 200. The divided conductor portion 221 and the divided conductor portion 222 are spaced apart from each other. The primary terminal 1421B is connected to the divided conductor portion 221, and the primary terminal 1422B is connected to the divided conductor portion 222. The current of the second phase flows through the divided conductor portion 221, the primary lead frame 140B, and the divided conductor portion 222.

The primary terminal portion 142A of the current sensor 10A and the primary terminal portion 142B of the current sensor 10B are arranged so as to be oriented in opposite directions in the Y-axis direction. The bus bar 210 and the bus bar 220 do not overlap in the thickness direction of the substrate 200 (Z-axis direction) in plan view. In plan view, the sealing portion 130A and the sealing portion 130B are positioned between the bus bar 210 and the bus bar 220.

Also, at least a part of the sealing portion 130A and at least a part of the sealing portion 130B overlap in the thickness direction (Z-axis direction) of the substrate 200. The side surface 130aA of the sealing portion 130A and the side surface 130bB of the sealing portion 130B are oriented in the same direction in the Y-axis direction, and the side surface 130bA of the sealing portion 130A and the side surface 130aB of the sealing portion 130B are oriented in the same direction in the Y-axis direction. That is, in plan view, the primary terminal portion 142A of the current sensor 10A and the primary terminal portion 142B of the current sensor 10B are oriented in opposite directions in the Y-axis direction.

The primary conductor portion 141A of the current sensor 10A may be located, in plan view, within the sealing portion 130A, on the side surface 130aA side of the sealing portion 130A with respect to the centroid of the sealing portion 130A. That is, the primary conductor portion 141A may be arranged shifted toward the side surface 130aA side of the sealing portion 130A from the centroid of the sealing portion 130A. Similarly, the primary conductor portion 141B of the current sensor 10B may be located, in plan view, within the sealing portion 130B, on the side surface 130aB side of the sealing portion 130B with respect to the centroid of the sealing portion 130B. That is, the primary conductor portion 141B may be arranged shifted toward the side surface 130aB side of the sealing portion 130B from the centroid of the sealing portion 130B.

By arranging the primary conductor portions 141A and 141B at such positions, and arranging the primary terminal portion 142A of the current sensor 10A and the primary terminal portion 142B of the current sensor 10B so as to be oriented in opposite directions in the Y-axis direction, the two magnetoelectric conversion elements 20A included in the current sensor 10A and the primary conductor portion 141B included in the current sensor 10B do not overlap in the thickness direction of the substrate 200 in plan view. In addition, the two magnetoelectric conversion elements 20B of the current sensor 10B and the primary conductor portion 141A of the current sensor 10A do not overlap in the thickness direction of the substrate 200 in plan view.

With such an arrangement, when viewed from the two magnetoelectric conversion elements 20A, the current of the second phase flowing through the primary conductor portion 141B exists only on the positive direction side of the Y-axis. Therefore, the direction of the magnetic field generated by the current of the second phase flowing through the primary conductor portion 141B, which affects the two magnetoelectric conversion elements 20A, becomes uniform. Similarly, when viewed from the two magnetoelectric conversion elements 20B, the current of the first phase flowing through the primary conductor portion 141A exists only on the negative direction side of the Y-axis. Therefore, the direction of the magnetic field generated by the current of the first phase flowing through the primary conductor portion 141A, which affects the two magnetoelectric conversion elements 20B, becomes uniform.

As described above, the current sensors 10A and 10B reduce noise components included in the output signal of one of the magnetoelectric conversion elements 20A and 20B and the output signal of another of the magnetoelectric conversion elements 20A and 20B, based on a difference between the output signal of one of the magnetoelectric conversion elements 20A and 20B and the output signal of another of the magnetoelectric conversion elements 20A and 20B. Therefore, if the influence of the magnetic field applied to the two magnetoelectric conversion elements 20A and 20B is the same, the influence can be effectively canceled by taking the difference between the output signals of the two magnetoelectric conversion elements 20A and 20B. Therefore, by setting the positional relationship between the two magnetoelectric conversion elements 20A and 20B and the primary conductor portions 141A and 141B with respect to the substrate 200 to the above positional relationship, the current sensor 10A can be made less susceptible to the influence of the current flowing through the bus bar 220, and the current sensor 10B can be made less susceptible to the influence of the current flowing through the bus bar 210.

Also, by arranging the bus bar 210 and the bus bar 220 on both surfaces of the substrate 200, the current sensor 10A can be made less susceptible to the influence of the magnetic field generated by the current of the second phase flowing through the primary conductor portion 141B. Furthermore, the current sensor 10B can be made less susceptible to the influence of the magnetic field generated by the current of the first phase flowing through the primary conductor portion 141A. Moreover, the area of the substrate 200 on which the plurality of bus bars 210, 220, and 230 and the current sensors 10A and 10B are mounted can be reduced.

It is preferable that the primary conductor portion 141A and the primary conductor portion 141B do not overlap in the thickness direction of the substrate 200 in plan view. This makes it possible to make the current sensors 10A and 10B less susceptible to the influence of the magnetic field generated by the current flowing through the bus bars 210 and 220 with respect to each other.

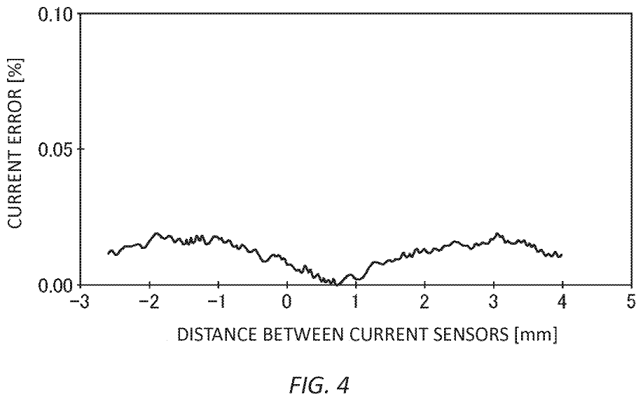

FIG. 4 shows an example of simulation results showing a magnitude of the current error detected by the current sensor 10A or the current sensor 10B according to a distance (mm) in the X-axis direction between the centroid of the current sensor 10A and the centroid of the current sensor 10B when the current measuring device according to the first embodiment is viewed in plan view. As shown in FIG. 4, it can be seen that the current error becomes smaller when the centroid of the current sensor 10B is shifted slightly relative to the centroid of the current sensor 10A, or when the centroid of the current sensor 10B is shifted largely relative to the centroid of the current sensor 10A, than when the distance between the centroid of the current sensor 10A and the centroid of the current sensor 10B is made zero.

The reason why the current error becomes smaller when the centroid of the current sensor 10B is shifted largely relative to the centroid of the current sensor 10A is that, if the distance between the current sensor 10A and the current sensor 10B is increased, the two magnetoelectric conversion elements 20 can be made less susceptible to the influence of the current flowing through the primary conductor portion 141 on the counterpart side.

The reason why the current error becomes smaller at a position where the centroid of the current sensor 10B is shifted slightly relative to the centroid of the current sensor 10A is that the change in the influence of the current flowing through the primary conductor portion 141 on the counterpart side received by the two magnetoelectric conversion elements 20 is small. When the change in the influence of the current is small, the influence can be effectively canceled by taking a difference between output signals of the two magnetoelectric conversion elements 20.

Here, if, in plan view, the primary conductor portion 141 has the line-symmetrical shape with respect to the perpendicular bisector of the line segment connecting the two magnetoelectric conversion elements 20 as the symmetry axis, it is possible to suppress variations in the influence of the current flowing through the primary conductor portion 141 on the counterpart side received by the two magnetoelectric conversion elements 20.

In view of the above point, in FIG. 3, it is preferable that the perpendicular bisector 24A of the line segment 23A connecting the two magnetoelectric conversion elements 20A does not overlap, in plan view, with the perpendicular bisector 24B of the line segment 23B connecting the two magnetoelectric conversion elements 20B. Thereby, the current sensor 10A and the current sensor 10B can be made less susceptible to the influence of magnetic noise from each other.

Furthermore, it is preferable that the perpendicular bisector 24A of the line segment 23A connecting the two magnetoelectric conversion elements 20A passes between the two magnetoelectric conversion elements 20B in plan view. Furthermore, it is preferable that the distance k in plan view between the perpendicular bisector 24A of the line segment 23A connecting the two magnetoelectric conversion elements 20A and the perpendicular bisector 24B of the line segment 23B connecting the two magnetoelectric conversion elements 20B is half the distance between the centroids of the two magnetoelectric conversion elements 20A or the two magnetoelectric conversion elements 20B. Actually, in FIG. 4, the condition under which the current error is minimized corresponds to a case where the distance k is half the distance between the centroids of the two magnetoelectric conversion elements 20A or the two magnetoelectric conversion elements 20B.

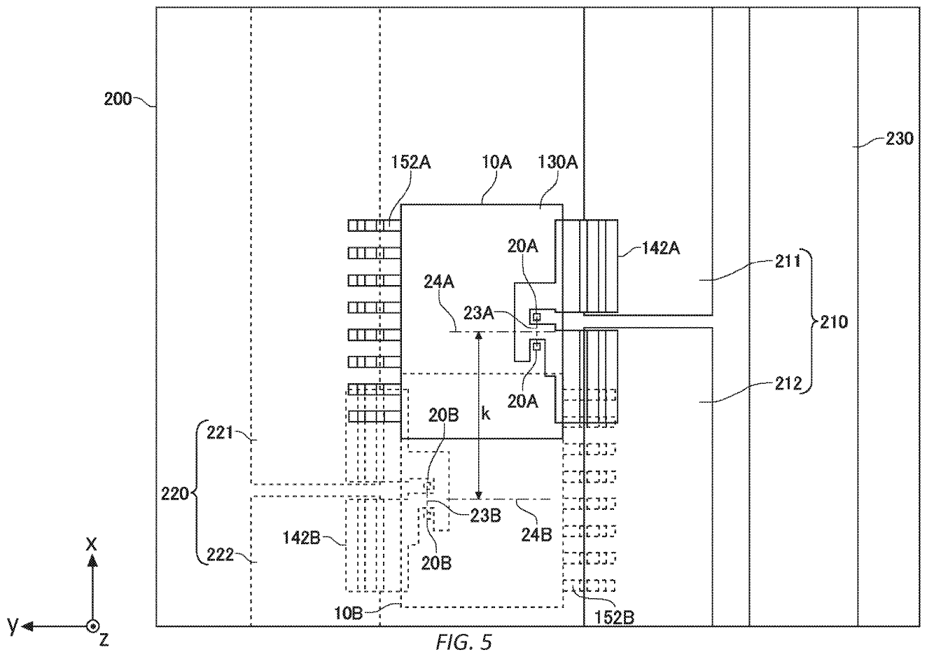

Alternatively, as shown in FIG. 4, the current error decreases by making the distance k in plan view between the perpendicular bisector 24A of the line segment 23A connecting the two magnetoelectric conversion elements 20A and the perpendicular bisector 24B of the line segment 23B connecting the two magnetoelectric conversion elements 20B at least 2.5 times the distance between the two magnetoelectric conversion elements 20A. Therefore, as shown in FIG. 5, the distance k is preferably at least 2.5 times the distance between the two magnetoelectric conversion elements 20A in plan view. Thereby, the current sensor 10A and the current sensor 10B can be made less susceptible to the influence of magnetic noise from each other.

The bus bar 230 is arranged on the first surface of the substrate 200, extends in the X-axis direction, is arranged at a position facing the current sensor 10A with the bus bar 210 interposed therebetween in the Y-axis direction, and carries current of the third phase. The bus bar 230 is arranged on the side opposite to one side of the bus bar 210 to which the primary terminal portion 142A of the current sensor 10A is connected. Thereby, the bus bar 230 can be arranged at a position away from the secondary terminal portion 152A of the current sensor 10A. Thereby, magnetic noise generated by the current flowing through the bus bar 230 can be made less likely to affect the signal flowing through the secondary terminal portion 152A. Furthermore, it is possible to easily ensure withstand voltage between the bus bar 230 and the circuit 300A.

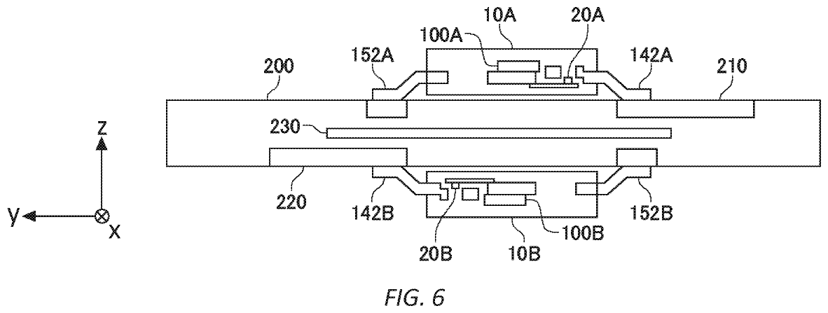

As shown in FIG. 6, the bus bar 230 may be arranged in an inner layer of the substrate 200 while extending in the X-axis direction. In this case, a part of the bus bar 230 may overlap with the bus bar 210 and the bus bar 220 in the thickness direction of the substrate 200. Thereby, the area of the substrate 200 can be further reduced.

In the above, an example has been described in which the bus bar 210 and the bus bar 220 are arranged at positions that do not overlap in the thickness direction of the substrate 200. However, the bus bar 210 and the bus bar 220 may be arranged at positions that overlap in the thickness direction of the substrate 200. Also, in the above, an example has been described in which, in plan view, the primary terminal portion 142A of the current sensor 10A and the primary terminal portion 142B of the current sensor 10B are oriented in opposite directions in the Y-axis direction. However, in plan view, the primary terminal portion 142A of the current sensor 10A and the primary terminal portion 142B of the current sensor 10B may be oriented in the same direction in the Y-axis direction.

Even in such a modified example, it is preferable that the perpendicular bisector 24A of the line segment 23A connecting the two magnetoelectric conversion elements 20A does not overlap, in plan view, with the perpendicular bisector 24B of the line segment 23B connecting the two magnetoelectric conversion elements 20B. Furthermore, it is preferable that the distance k in plan view between the perpendicular bisector 24A of the line segment 23A connecting the two magnetoelectric conversion elements 20A and the perpendicular bisector 24B of the line segment 23B connecting the two magnetoelectric conversion elements 20B is half the distance between the centroids of the two magnetoelectric conversion elements 20A or the two magnetoelectric conversion elements 20B. Alternatively, it is preferable that the distance k between the perpendicular bisector 24A of the line segment 23A connecting the two magnetoelectric conversion elements 20A and the perpendicular bisector 24B of the line segment 23B connecting the two magnetoelectric conversion elements 20B is a distance that is 2.5 times or more the distance between the two magnetoelectric conversion elements 20A in plan view.

Next, the current measuring device according to the second embodiment in which the primary terminal portion 142A of the current sensor 10A and the primary terminal portion 142B of the current sensor 10B are oriented in the same direction in the Y-axis direction in plan view will be described. The current measuring device according to the second embodiment includes the current sensor 10A and the current sensor 10B. The current sensor 10A and the current sensor 10B may have the same configuration as the current sensor 10 in the first embodiment. That is, they may have the same configuration as the current sensor 10 shown in FIGS. 1A and 1B.

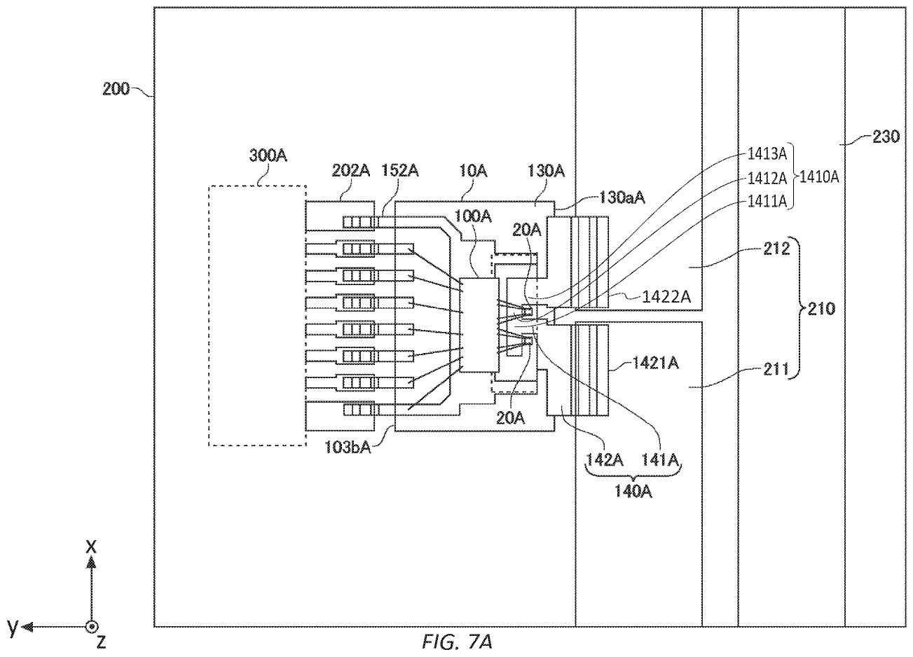

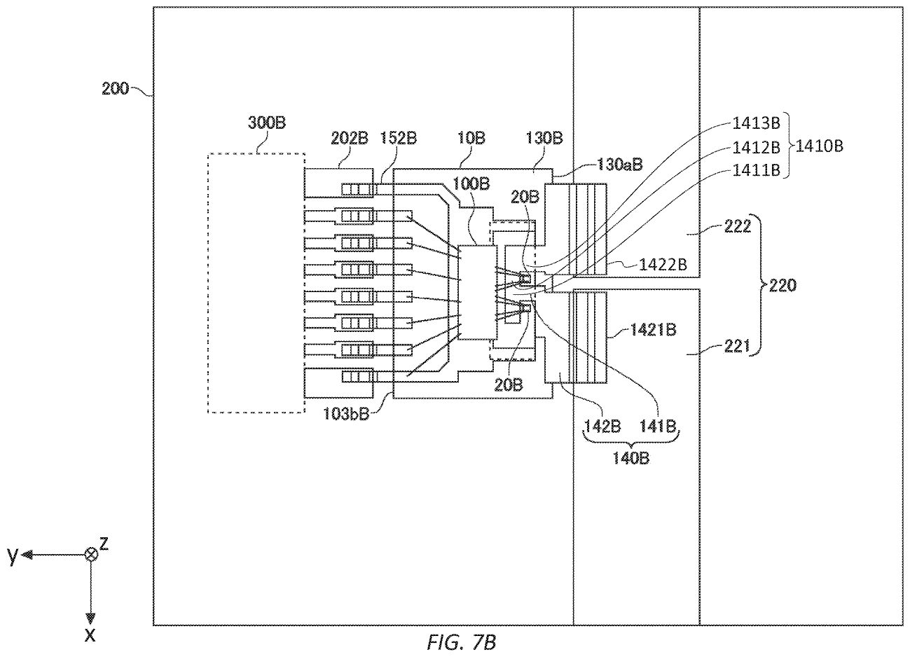

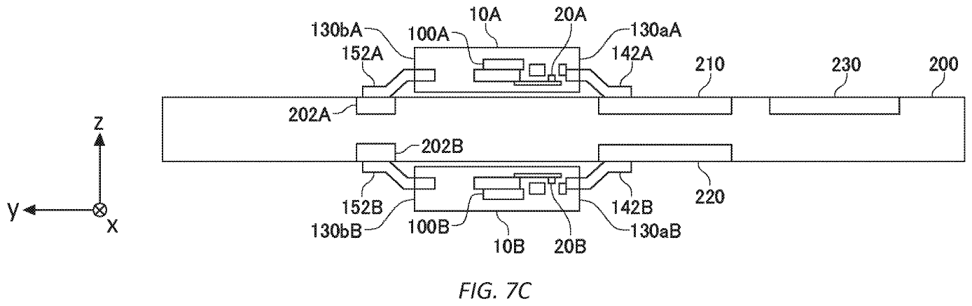

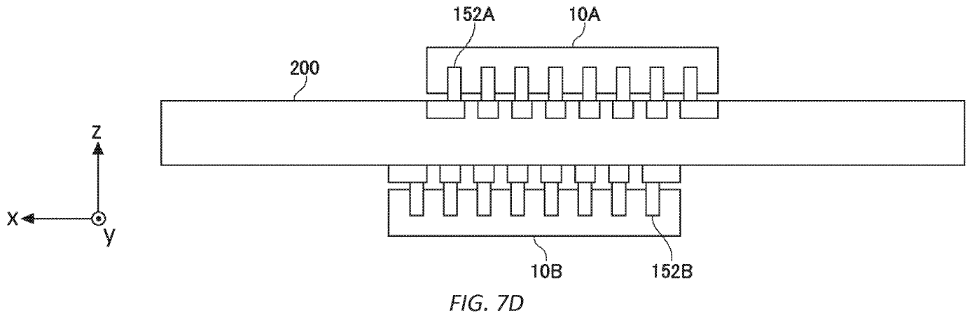

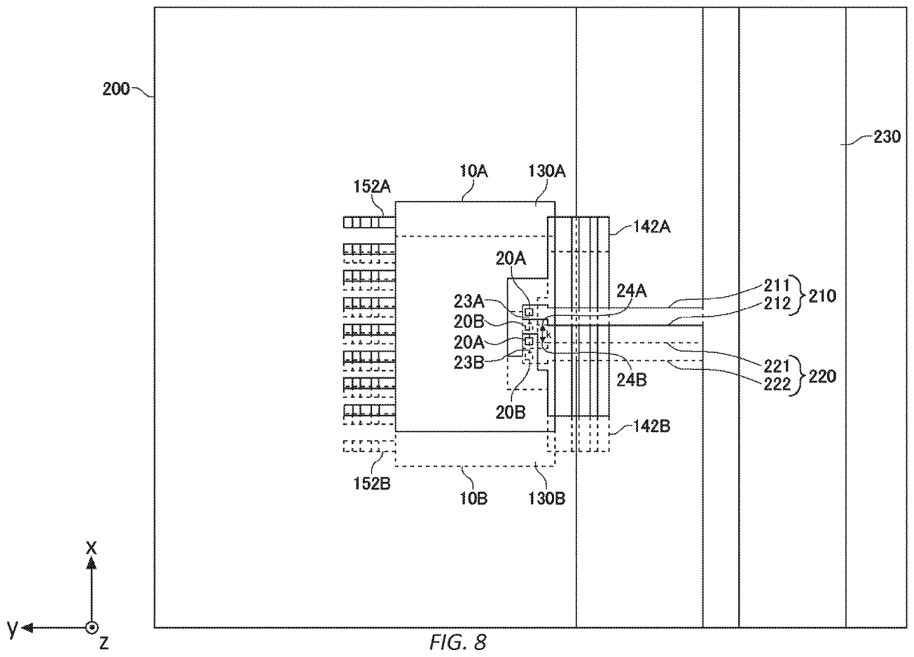

FIG. 7A is a plan view of the substrate 200 as viewed from the first surface side on which the current sensor 10A is mounted in the second embodiment. FIG. 7B is a plan view of the substrate 200 as viewed from the second surface side opposite to the first surface on which the current sensor 10B is mounted in the second embodiment. FIG. 7C is a schematic cross-sectional view of the substrate 200 with the current sensor 10A and the current sensor 10B mounted thereon, as viewed from the negative side to the positive side in the X-axis direction in the second embodiment. FIG. 7D is a schematic cross-sectional view of the substrate 200 with the current sensor 10A and the current sensor 10B mounted thereon, as viewed from the positive side to the negative side in the Y-axis direction in the second embodiment. FIG. 8 is a schematic plan view in which, in the second embodiment, the substrate 200 is viewed from the first surface side, and the current sensor 10B and the bus bar 220 arranged on the second surface side are indicated by broken lines.

The current measuring device includes, on the first surface of the substrate 200, the bus bar 210 that extends along the X-axis direction and through which current of a first phase flows. The current measuring device further includes, on the second surface of the substrate 200, the bus bar 220 that extends along the X-axis direction and through which current of a second phase flows. In addition, the current measuring device further includes, on the first surface of the substrate 200, the bus bar 230 that extends along the X-axis direction and through which current of a third phase flows. The bus bar 210, the bus bar 220, and the bus bar 230 may be arranged in parallel in plan view.

The current sensor 10A measures the current of the first phase flowing through the bus bar 210. The current sensor 10B measures the current of the second phase flowing through the bus bar 220. The circuit 300A including a power supply that supplies power to the current sensor 10A, a signal processing circuit that processes a signal output from the current sensor 10A, and the like is connected to the secondary terminal portion 152A of the current sensor 10A via the pad 202A on the first surface of the substrate 200. The circuit 300B including a power supply that supplies power to the current sensor 10B, a signal processing circuit that processes a signal output from the current sensor 10B, and the like is connected to the secondary terminal portion 152B of the current sensor 10B via the pad 202B on the second surface of the substrate 200. At least a part of the circuit 300A and the circuit 300B may be the common circuit.

The bus bar 210 has two divided conductor portions 211 and 212 extending along the X-axis direction along the first surface of the substrate 200. The divided conductor portion 211 and the divided conductor portion 212 are spaced apart from each other. The primary terminal 1421A is connected to the divided conductor portion 211, and the primary terminal 1422A is connected to the divided conductor portion 212. The current of the first phase flows through the divided conductor portion 211, the primary lead frame 140, and the divided conductor portion 212.

The bus bar 220 has, like the bus bar 210, two divided conductor portions 221 and 222 extending along the X-axis direction along the second surface of the substrate 200. The divided conductor portion 221 and the divided conductor portion 222 are spaced apart from each other. The primary terminal 1421B is connected to the divided conductor portion 221, and the primary terminal 1422B is connected to the divided conductor portion 222. The current of the second phase flows through the divided conductor portion 221, the primary lead frame 140B, and the divided conductor portion 222. A part of the bus bar 220 overlaps the bus bar 210 when viewed from the thickness direction of the substrate 200 (the Z-axis direction).

The primary terminal portion 142A of the current sensor 10A and the primary terminal portion 142B of the current sensor 10B are arranged so as to be oriented in the same direction in the Y-axis direction.

At least a part of the sealing portion 130A and at least a part of the sealing portion 130B overlap in the thickness direction (the Z-axis direction) of the substrate 200. The side surface 130aA of the sealing portion 130A and the side surface 130aB of the sealing portion 130B are oriented in the same direction in the Y-axis direction, and the side surface 130bA of the sealing portion 130A and the side surface 130bB of the sealing portion 130B are oriented in the same direction in the Y-axis direction. That is, in plan view, the primary terminal portion 142A of the current sensor 10A and the primary terminal portion 142B of the current sensor 10B are oriented in the same direction in the Y-axis direction.

The primary conductor portion 141A of the current sensor 10A may be located, in plan view, within the sealing portion 130A, on the side surface 130aA side of the sealing portion 130A with respect to the centroid of the sealing portion 130A. That is, the primary conductor portion 141A may be arranged shifted toward the side surface 130aA side of the sealing portion 130A from the centroid of the sealing portion 130A. Similarly, the primary conductor portion 141B of the current sensor 10B may be located, in plan view, within the sealing portion 130B, on the side surface 130aB side of the sealing portion 130B with respect to the centroid of the sealing portion 130B. That is, the primary conductor portion 141B may be arranged shifted toward the side surface 130aB side of the sealing portion 130B from the centroid of the sealing portion 130B.

The primary conductor portions 141A and 141B are arranged at such positions, and the primary terminal portion 142A of the current sensor 10A and the primary terminal portion 142B of the current sensor 10B are arranged so as to be oriented in the same direction in the Y-axis direction. Further, the current sensor 10B may be arranged shifted at least in the X-axis direction relative to the current sensor 10A in plan view. The primary conductor portion 141B may be congruent in shape with the primary conductor portion 141A, and may be arranged shifted relative to the primary conductor portion 141A in plan view. One of the two magnetoelectric conversion elements 20B may be arranged between the two magnetoelectric conversion elements 20A in the Y-axis direction in plan view. In plan view, the two magnetoelectric conversion elements 20B may overlap in the thickness direction (the Z-axis direction) with at least a part of at least one of the portion 1411A, the portion 1413A, and the connecting portion 1412A of the bent portion 1410A. Similarly, the two magnetoelectric conversion elements 20A may overlap in the thickness direction (the Z-axis direction) with at least a part of at least one of the portion 1411B, the portion 1413B, and the connecting portion 1412B of the bent portion 1410B.

In the current measuring device according to the second embodiment, in plan view, in the X-axis direction, it is preferable that at least one of the pair of magnetoelectric conversion elements 20B of another current sensor 10B exists between the pair of magnetoelectric conversion elements 20A of one current sensor 10A, or that at least one of the pair of magnetoelectric conversion elements 20B of another current sensor 10B overlaps in the thickness direction with at least a part of at least one of the portion 1411, the connecting portion 1412, or the portion 1413 of the bent portion 1410 of the one current sensor 10A. This makes it possible to make the current sensors 10A and 10B less susceptible to the influence of the magnetic field generated by the current flowing through the bus bars 210 and 220 with respect to each other.

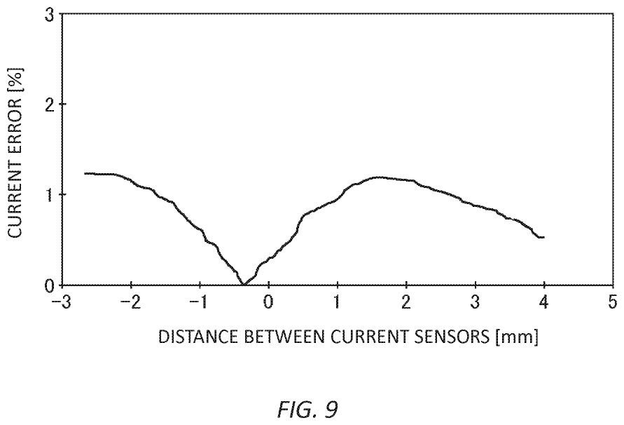

FIG. 9 shows an example of the simulation result showing the magnitude of a current error detected by the current sensor 10A or the current sensor 10B according to the distance (mm) in the X-axis direction between the centroid of the current sensor 10A and the centroid of the current sensor 10B when the current measuring device according to the second embodiment is viewed in plan view.

As shown in FIG. 9, it can be seen that the current error becomes smaller when the centroid of the current sensor 10B is shifted slightly relative to the centroid of the current sensor 10A, or when the centroid of the current sensor 10B is shifted largely relative to the centroid of the current sensor 10A, than when the distance between the centroid of the current sensor 10A and the centroid of the current sensor 10B is made zero. The reason why the current error becomes smaller when the centroid of the current sensor 10B is shifted largely relative to the centroid of the current sensor 10A is that, if the distance between the current sensor 10A and the current sensor 10B is increased, the two magnetoelectric conversion elements 20 can be made less susceptible to the influence of the current flowing through the primary conductor portion 141 on the counterpart side.

The reason why the current error becomes smaller at a position where the centroid of the current sensor 10B is shifted slightly relative to the centroid of the current sensor 10A is that the change in the influence of the current flowing through the primary conductor portion 141 on the counterpart side received by the two magnetoelectric conversion elements 20 is small. When the change in the influence of the current is small, the influence can be effectively canceled by taking a difference between output signals of the two magnetoelectric conversion elements 20.

Here, if, in plan view, the primary conductor portion 141 has the line-symmetrical shape with respect to the perpendicular bisector of the line segment connecting the two magnetoelectric conversion elements 20 as the symmetry axis, it is possible to suppress variations in the influence of the current flowing through the primary conductor portion 141 on the counterpart side received by the two magnetoelectric conversion elements 20.

In consideration of the above point, in FIG. 8, it is preferable that the perpendicular bisector 24A of the line segment 23A connecting the two magnetoelectric conversion elements 20A does not overlap, in plan view, with the perpendicular bisector 24B of the line segment 23B connecting the two magnetoelectric conversion elements 20B. As a result, the current sensor 10A and the current sensor 10B can be made less susceptible to the influence of magnetic noise from each other.

Furthermore, it is preferable that the perpendicular bisector 24A of the line segment 23A connecting the two magnetoelectric conversion elements 20A passes between the two magnetoelectric conversion elements 20B in plan view. Furthermore, it is preferable that the distance k in plan view between the perpendicular bisector 24A of the line segment 23A connecting the two magnetoelectric conversion elements 20A and the perpendicular bisector 24B of the line segment 23B connecting the two magnetoelectric conversion elements 20B is half the distance between the centroids of the two magnetoelectric conversion elements 20A or the two magnetoelectric conversion elements 20B. Actually, in FIG. 8, the condition under which the current error is minimized corresponds to a case where the distance k is half the distance between the centroids of the two magnetoelectric conversion elements 20A or the two magnetoelectric conversion elements 20B.

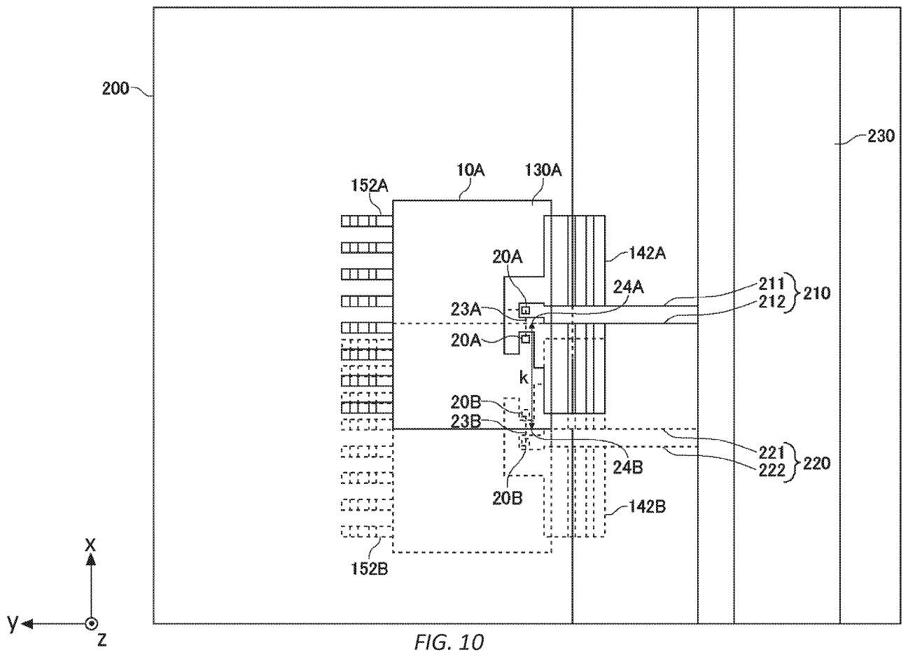

Alternatively, as shown in FIG. 8, the current error decreases by making the distance k in plan view between the perpendicular bisector 24A of the line segment 23A connecting the two magnetoelectric conversion elements 20A and the perpendicular bisector 24B of the line segment 23B connecting the two magnetoelectric conversion elements 20B at least 2.5 times the distance between the two magnetoelectric conversion elements 20A. Therefore, as shown in FIG. 10, the distance k is preferably at least 2.5 times the distance between the two magnetoelectric conversion elements 20A in plan view. As a result, the current sensor 10A and the current sensor 10B can be made less susceptible to the influence of magnetic noise from each other.

The bus bar 230 is arranged on the first surface of the substrate 200, extends in the X-axis direction, is arranged at a position facing the current sensor 10A with the bus bar 210 interposed therebetween in the Y-axis direction, and carries current of the third phase. The bus bar 230 is arranged on the side opposite to one side of the bus bar 210 to which the primary terminal portion 142A of the current sensor 10A is connected. As a result, the bus bar 230 can be arranged at the position away from the secondary terminal portion 152A of the current sensor 10A. As a result, magnetic noise generated by the current flowing through the bus bar 230 can be made less likely to affect the signal flowing through the secondary terminal portion 152A. Furthermore, it is possible to easily ensure withstand voltage between the bus bar 230 and the circuit 300A.

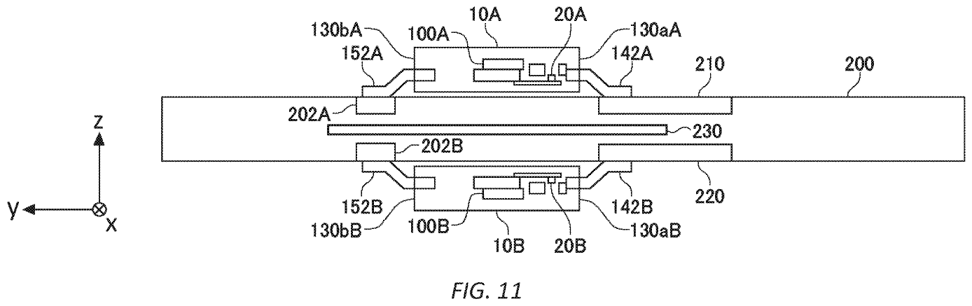

As shown in FIG. 11, the bus bar 230 may be arranged in an inner layer of the substrate 200 while extending in the X-axis direction. In this case, a part of the bus bar 230 may overlap with the bus bar 210 and the bus bar 220 in the thickness direction of the substrate 200. As a result, the area of the substrate 200 can be further reduced.

While the embodiments of the present invention have been described, the technical scope of the invention is not limited to the above described embodiments. It is apparent to persons skilled in the art that various alterations or improvements can be added to the above-described embodiments. It is also apparent from the scope of the claims that the embodiments to which such alterations or improvements are added can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10, 10A, and 10B current sensors
20, 20A, and 20B magnetoelectric conversion elements
100 signal processing IC
22 and 108 wires
23A and 23B line segments
24A and 24B perpendicular bisectors
120 element support portion
130, 130A, and 130B sealing portions
130a, 130aA, and 130aB side surfaces
130b, 130bA, and 130bB side surfaces
140 primary lead frame
141, 141A, and 141B primary conductor portions
144 step portion
150 secondary lead frame
151 IC Support Portion
152, 152A, and 152B secondary terminal portions
200 substrate
210, 220, and 230 bus bars
211 and 212 divided conductor portions
221 and 222 divided conductor portions
300A and 300B circuits
1410 bent portion
1411 portion
1412 connecting portion
1413 portion
1414 extension
1415 connection
1416 and 1417 slit
1421, 1421A, 1421B, 1422, 1422A, 1422B primary terminals
1521 secondary terminal.

What is claimed is:

1. A current measuring device comprising:
a substrate;
a first bus bar arranged on a first surface of the substrate;
a second bus bar arranged on a second surface opposite to the first surface of the substrate;
a first current sensor arranged on the first surface of the substrate and measuring a first current flowing through the first bus bar; and
a second current sensor arranged on the second surface of the substrate and measuring a second current flowing through the second bus bar, wherein
the first current sensor has
at least one first magnetoelectric conversion element,
a first primary lead frame which includes a first primary terminal portion connected to the first bus bar and a first primary conductor portion connected to the first primary terminal portion, and through which the first current to be measured by the at least one first magnetoelectric conversion element flows via the first primary terminal portion and the first primary conductor portion,
a first signal processing IC that processes a signal output from the at least one first magnetoelectric conversion element, and
a first sealing portion that seals the at least one first magnetoelectric conversion element, the first primary conductor portion, and the first signal processing IC,
the second current sensor has
at least one second magnetoelectric conversion element,
a second primary lead frame which includes a second primary terminal portion connected to the second bus bar and a second primary conductor portion connected to the second primary terminal portion, and through which the second current to be measured by the at least one second magnetoelectric conversion element flows via the second primary terminal portion and the second primary conductor portion,
a second signal processing IC that processes a signal output from the at least one second magnetoelectric conversion element, and
a second sealing portion that seals the at least one second magnetoelectric conversion element, the second primary conductor portion, and the second signal processing IC,
at least a part of the first sealing portion and at least a part of the second sealing portion overlap in a thickness direction of the substrate,
the at least one first magnetoelectric conversion element and the second primary conductor portion do not overlap in the thickness direction of the substrate in plan view, and
the at least one second magnetoelectric conversion element and the first primary conductor portion do not overlap in the thickness direction of the substrate in plan view.

2. The current measuring device according to claim 1, wherein the first primary conductor portion and the second primary conductor portion do not overlap in the thickness direction of the substrate in plan view.

3. A current measuring device comprising:
a substrate;
a first bus bar arranged on a first surface of the substrate;
a second bus bar arranged on a second surface opposite to the first surface of the substrate;
a first current sensor arranged on the first surface of the substrate and measuring a first current flowing through the first bus bar; and
a second current sensor arranged on the second surface of the substrate and measuring a second current flowing through the second bus bar, wherein
the first current sensor has
at least two first magnetoelectric conversion elements,
a first primary lead frame which includes a first primary terminal portion connected to the first bus bar and a first primary conductor portion connected to the first primary terminal portion, and through which the first current to be measured by the at least two first magnetoelectric conversion elements flows via the first primary terminal portion and the first primary conductor portion,
a first signal processing IC that processes a signal output from the at least two first magnetoelectric conversion elements, and
a first sealing portion that seals the at least two first magnetoelectric conversion elements, the first primary conductor portion, and the first signal processing IC,
the second current sensor has
at least two second magnetoelectric conversion elements,
a second primary lead frame which includes a second primary terminal portion connected to the second bus bar and a second primary conductor portion connected to the second primary terminal portion, and through which the second current to be measured by the at least two second magnetoelectric conversion elements flows via the second primary terminal portion and the second primary conductor portion,
a second signal processing IC that processes a signal output from the at least two second magnetoelectric conversion elements, and
a second sealing portion that seals the at least two second magnetoelectric conversion elements, the second primary conductor portion, and the second signal processing IC,
at least a part of the first sealing portion and at least a part of the second sealing portion overlap in a thickness direction of the substrate,
a direction along the first surface of the substrate and in which the first bus bar extends is defined as a first direction,
a direction along the first surface of the substrate and intersecting the first direction is defined as a second direction, and
at least one of the at least two second magnetoelectric conversion elements is between the at least two first magnetoelectric conversion elements in the first direction in plan view.

4. A current measuring device comprising:
a substrate;
a first bus bar arranged on a first surface of the substrate;
a second bus bar arranged on a second surface opposite to the first surface of the substrate;
a first current sensor arranged on the first surface of the substrate and measuring a first current flowing through the first bus bar; and
a second current sensor arranged on the second surface of the substrate and measuring a second current flowing through the second bus bar, wherein
the first current sensor has
at least one first magnetoelectric conversion element,
a first primary lead frame which includes a first primary terminal portion connected to the first bus bar and a first primary conductor portion connected to the first primary terminal portion, and through which the first current to be measured by the at least one first magnetoelectric conversion element flows via the first primary terminal portion and the first primary conductor portion,
a first signal processing IC that processes a signal output from the at least one first magnetoelectric conversion element, and
a first sealing portion that seals the at least one first magnetoelectric conversion element, the first primary conductor portion, and the first signal processing IC,
the second current sensor has
at least one second magnetoelectric conversion element,
a second primary lead frame which includes a second primary terminal portion connected to the second bus bar and a second primary conductor portion connected to the second primary terminal portion, and through which the second current to be measured by the at least one second magnetoelectric conversion element flows via the second primary terminal portion and the second primary conductor portion,
a second signal processing IC that processes a signal output from the at least one second magnetoelectric conversion element, and
a second sealing portion that seals the at least one second magnetoelectric conversion element, the second primary conductor portion, and the second signal processing IC,
at least a part of the first sealing portion and at least a part of the second sealing portion overlap in a thickness direction of the substrate,
a direction along the first surface of the substrate and in which the first bus bar extends is defined as a first direction,
a direction along the first surface of the substrate and intersecting the first direction is defined as a second direction,
the first bus bar has two first divided conductor portions extending along the first direction,
the second bus bar has two second divided conductor portions extending along the first direction,
in the first current sensor,
the first current sensor has a pair of first primary terminals exposed from the first sealing portion,
one of the two first divided conductor portions is connected to one of the pair of first primary terminals,
another of the two first divided conductor portions is connected to another of the pair of first primary terminals,
the first primary conductor portion has a first bent portion connecting one of the pair of first primary terminals and another of the pair of first primary terminals,
the first bent portion includes a first portion and a second portion each extending in the second direction and a connecting portion connecting the first portion and the second portion and extending in the first direction, and
the at least one second magnetoelectric conversion element overlaps at least a part of at least one of the first portion, the second portion, or the connecting portion of the first bent portion in the thickness direction in plan view.

5. The current measuring device according to claim 1, wherein
the first bus bar has two first divided conductor portions extending along a first direction along the first surface of the substrate,
the second bus bar has two second divided conductor portions extending along the first direction along the second surface of the substrate,
the first sealing portion has a first side surface and a second side surface opposite to each other in a second direction intersecting the first direction along the first surface of the substrate,
the first primary terminal portion has a pair of first primary terminals exposed from the first side surface of the first sealing portion,
one of the two first divided conductor portions is connected to one of the pair of first primary terminals,
another of the two first divided conductor portions is connected to another of the pair of first primary terminals,
the first primary conductor portion has a first connecting portion connecting one of the pair of first primary terminals and another of the pair of first primary terminals,
the second sealing portion has a first side surface and a second side surface opposite to each other in the second direction along the second surface of the substrate,
the second primary terminal portion has a pair of second primary terminals exposed from the first side surface of the second sealing portion,
one of the two second divided conductor portions is connected to one of the pair of second primary terminals,
another of the two second divided conductor portions is connected to another of the pair of second primary terminals, and
the second primary conductor portion has a second connecting portion connecting one of the pair of second primary terminals and another of the pair of second primary terminals.

6. The current measuring device according to claim 2, wherein
the first bus bar has two first divided conductor portions extending along a first direction along the first surface of the substrate,
the second bus bar has two second divided conductor portions extending along the first direction along the second surface of the substrate,
the first sealing portion has a first side surface and a second side surface opposite to each other in a second direction intersecting the first direction along the first surface of the substrate,
the first primary terminal portion has a pair of first primary terminals exposed from the first side surface of the first sealing portion,
one of the two first divided conductor portions is connected to one of the pair of first primary terminals,
another of the two first divided conductor portions is connected to another of the pair of first primary terminals,
the first primary conductor portion has a first connecting portion connecting one of the pair of first primary terminals and another of the pair of first primary terminals,
the second sealing portion has a first side surface and a second side surface opposite to each other in the second direction along the second surface of the substrate,
the second primary terminal portion has a pair of second primary terminals exposed from the first side surface of the second sealing portion,
one of the two second divided conductor portions is connected to one of the pair of second primary terminals,
another of the two second divided conductor portions is connected to another of the pair of second primary terminals, and
the second primary conductor portion has a second connecting portion connecting one of the pair of second primary terminals and another of the pair of second primary terminals.

7. The current measuring device according to claim 3, wherein
the first bus bar has two first divided conductor portions extending along a first direction along the first surface of the substrate,
the second bus bar has two second divided conductor portions extending along the first direction along the second surface of the substrate,
the first sealing portion has a first side surface and a second side surface opposite to each other in a second direction intersecting the first direction along the first surface of the substrate,
the first primary terminal portion has a pair of first primary terminals exposed from the first side surface of the first sealing portion,
one of the two first divided conductor portions is connected to one of the pair of first primary terminals,
another of the two first divided conductor portions is connected to another of the pair of first primary terminals,
the first primary conductor portion has a first connecting portion connecting one of the pair of first primary terminals and another of the pair of first primary terminals,
the second sealing portion has a first side surface and a second side surface opposite to each other in the second direction along the second surface of the substrate,
the second primary terminal portion has a pair of second primary terminals exposed from the first side surface of the second sealing portion,
one of the two second divided conductor portions is connected to one of the pair of second primary terminals,
another of the two second divided conductor portions is connected to another of the pair of second primary terminals, and
the second primary conductor portion has a second connecting portion connecting one of the pair of second primary terminals and another of the pair of second primary terminals.

8. The current measuring device according to claim 5, wherein
the first current sensor has two first magnetoelectric conversion elements as the at least one first magnetoelectric conversion element,
the second current sensor has two second magnetoelectric conversion elements as the at least one second magnetoelectric conversion element,
at least a part of the two first magnetoelectric conversion elements is surrounded by the first connecting portion in plan view, and
at least a part of the two second magnetoelectric conversion elements is surrounded by the second connecting portion in plan view.

9. The current measuring device according to claim 8, wherein
the two first magnetoelectric conversion elements are arranged facing each other with a part of the first connecting portion interposed therebetween, and
the two second magnetoelectric conversion elements are arranged facing each other with a part of the second connecting portion interposed therebetween.

10. The current measuring device according to claim 8, wherein
the first connecting portion includes a first portion connected to one of the pair of first primary terminals and extending in the second direction, a first bent portion bent from the first portion, and a second portion extending in the second direction from the first bent portion and connected to another of the pair of first primary terminals,
the second connecting portion includes a third portion connected to one of the pair of second primary terminals and extending in the second direction, a second bent portion bent from the third portion, and a fourth portion extending in the second direction from the second bent portion and connected to another of the pair of second primary terminals,
the two first magnetoelectric conversion elements are arranged facing each other in the first direction with the first portion interposed therebetween, and
the two second magnetoelectric conversion elements are arranged facing each other in the first direction with the third portion interposed therebetween.

11. The current measuring device according to claim 10, wherein a perpendicular bisector of a line segment connecting the two first magnetoelectric conversion elements does not overlap in plan view with a perpendicular bisector of a line segment connecting the two second magnetoelectric conversion elements.

12. The current measuring device according to claim 10, wherein a perpendicular bisector of a line segment connecting the two first magnetoelectric conversion elements passes between the two second magnetoelectric conversion elements in plan view.

13. The current measuring device according to claim 10, wherein a distance between a perpendicular bisector of a line segment connecting the two first magnetoelectric conversion elements and a perpendicular bisector of a line segment connecting the two second magnetoelectric conversion elements is a distance that is 2.5 times or more a distance between the two first magnetoelectric conversion elements in plan view.

14. The current measuring device according to claim 1, wherein
the first bus bar has two first divided conductor portions extending along a first direction along the first surface of the substrate,
the second bus bar has two second divided conductor portions extending along the first direction along the second surface of the substrate,
the first sealing portion has a first side surface and a second side surface opposite to each other in a second direction intersecting the first direction along the first surface of the substrate,
the first primary terminal portion has a pair of first primary terminals exposed from the first side surface of the first sealing portion,
one of the two first divided conductor portions is connected to one of the pair of first primary terminals,
another of the two first divided conductor portions is connected to another of the pair of first primary terminals,
the first primary conductor portion has a first bent portion connecting one of the pair of first primary terminals and another of the pair of first primary terminals,
the second sealing portion has a first side surface and a second side surface opposite to each other in the second direction along the second surface of the substrate,
the second primary terminal portion has a pair of second primary terminals exposed from the first side surface of the second sealing portion,
one of the two second divided conductor portions is connected to one of the pair of second primary terminals,
another of the two second divided conductor portions is connected to another of the pair of second primary terminals,
the second primary conductor portion has a second bent portion connecting one of the pair of second primary terminals and another of the pair of second primary terminals,
the first side surface of the first sealing portion and the second side surface of the second sealing portion are oriented in a same direction in the second direction, and
the second side surface of the first sealing portion and the first side surface of the second sealing portion are oriented in a same direction in the second direction.

15. The current measuring device according to claim 14, wherein
the first primary conductor portion is located in the first sealing portion in plan view on a first side surface side of the first sealing portion with respect to a centroid of the first sealing portion, and
the second primary conductor portion is located in the second sealing portion in plan view on a first side surface side of the second sealing portion with respect to a centroid of the second sealing portion.

16. The current measuring device according to claim 5, wherein
the first current sensor further has a first secondary lead frame that includes a first secondary terminal portion arranged facing the first primary terminal portion with the first signal processing IC interposed therebetween in plan view, exposed from the second side surface of the first sealing portion, and electrically connected to the first signal processing IC, and a first support portion supporting the first signal processing IC, and electrically insulated from the first primary lead frame, and
the second current sensor further has a second secondary lead frame that includes a second secondary terminal portion arranged facing the second primary terminal portion with the second signal processing IC interposed therebetween in plan view, exposed from the second side surface of the second sealing portion, and electrically connected to the second signal processing IC, and a second support portion supporting the second signal processing IC, and electrically insulated from the second primary lead frame.

17. The current measuring device according to claim 1, wherein the first bus bar and the second bus bar do not overlap in the thickness direction of the substrate.

18. The current measuring device according to claim 3, wherein the first bus bar and the second bus bar overlap at least in part in the thickness direction of the substrate.

19. The current measuring device according to claim 5, further comprising: a third bus bar which is arranged on the first surface of the substrate, extends in the first direction, and is arranged at a position facing the first current sensor with the first bus bar interposed therebetween in the second direction, and through which a third current flows.

20. The current measuring device according to claim 5, further comprising:
a third bus bar which is arranged in an inner layer of the substrate, and extends in the first direction, and through which a third current flows, wherein a part of the third bus bar overlaps the first bus bar and the second bus bar in the thickness direction of the substrate.
